(19) United States
(12) Patent Application Publication
(10) Pub. No.: US 2014/0015596 A1
(43) Pub. Date: Jan. 16, 2014

(54) MAGNETIC FIELD SWITCHES

(71) Applicants: Bryan A. Martin, Grand Rapids, MI (US); Jerry Cummins, Portland, MI (US)

(72) Inventors: Bryan A. Martin, Grand Rapids, MI (US); Jerry Cummins, Portland, MI (US)

(21) Appl. No.: 13/867,002

(22) Filed: Apr. 19, 2013

Related U.S. Application Data
(60) Provisional application No. 61/636,064, filed on Apr. 20, 2012.

(51) Int. Cl. H03K 17/97

(52) U.S. Cl. CPC H03K 17/97
USPC 327/517

(57) ABSTRACT

A magnetic field switch, comprising: A housing defining an interior space containing (a) a first permanent magnet, (b) a Hall Effect sensor, and (c) a switch device connected to the Hall Effect sensor and having a switching status varying in accordance with magnetic induction at the Hall Effect sensor; and a push-button reciprocally movably associated with the housing, the push-button including a second permanent magnet associated therewith, the push-button having a neutral position and an applied position. The first and second permanent magnets are spaced apart with the Hall Effect sensor and the switch device disposed therebetween. The first and second magnets have poles of the same polarity facing one another. The first and second permanent magnets each generate a magnetic field, the opposing magnetic fields meeting at a boundary region in the space between the first and second permanent magnets. In the neutral position of the push-button, the boundary region is positioned immediately above the Hall Effect sensor. In the applied position of the push-button, the boundary region passes through and activates the Hall Effect sensor.

### CROSS-REFERENCE TO RELATED APPLICATIONS

This application is related to, and claims the benefit of priority from, U.S. Provisional Application Ser. No. 61/636,064, the disclosure of which is incorporated herein by reference in its entirety.

### FIELD OF THE INVENTION

The invention relates to magnetic field switches having one or more sensors utilizing the Hall Effect to detect changes in a magnetic field effected by the movement of one or more permanent magnets upon actuation of a button, the detected change being translated into changes in the state of an associated switch device.

### BACKGROUND OF THE INVENTION

Life-cycle requirements are continuously increasing as products are expected to last longer and perform better. Switches are no exception to this rule. Yet switches have moving parts and springs that wear out, as well as contacts that corrode and oxidize over thousands of cycles. Additionally, they must be protected from water intrusion, shielded from debris during assembly, and carefully designed to give consistent tactile feedback to the operator. One particularly significant issue in the design of conventional switches is the longevity of the electrical contact points. During normal operation, natural electrical arcing occurs, which causes these points to carbonize, oxidize, and/or erode. This effect can be overcome somewhat using expensive board plating, high-speed springs, etc. Unfortunately, these solutions are costly and, moreover, will still break down over time.

Magnetic field switches are known. For example, U.S. Pat. No. 5,554,964, the disclosure of which is incorporated herein by reference in its entirety, discloses a microswitch with two permanent magnets having in one embodiment poles of the same polarity facing one another. The magnets are separated by an air gap. The magnets generate magnetic fields defining a boundary region. A magnetic field sensor is disposed in the air gap proximate the boundary region, in the neutral zone between the two magnets. A switch device is connected to the magnetic field sensor and has a switching status varying in accordance with magnetic induction at the magnetic field sensor, which induction is varied as one of the magnets is moved toward the other upon actuation of the switch.

While magnetic field switches address some of the shortcomings of more conventional electro-mechanical switches, their design is still capable of improvement.

### SUMMARY OF THE DISCLOSURE

Disclosed herein are magnetic field switches which, in one embodiment, comprise a housing defining an interior space containing (a) a first permanent magnet, (b) a Hall Effect sensor, and (c) a switch device being connected to said Hall Effect sensor and having a switching status varying in accordance with magnetic induction at said Hall Effect sensor; and a push-button reciprocally movably associated with the housing, the push-button including a second permanent magnet associated therewith, and the push-button having a neutral position and an applied position. The first and second permanent magnets are spaced apart with the Hall Effect sensor and the switch device disposed therebetween. The first and second magnets have poles of the same polarity facing one another. The first and second permanent magnets each generate a magnetic field, the opposing magnetic fields meeting at a boundary region in the space between the first and second permanent magnets. In the neutral position of the push-button, the boundary region is positioned immediately above the Hall Effect sensor. In the applied position of the push-button, the boundary region passes through and activates the Hall Effect sensor.

In another embodiment, the magnetic field switch comprises a housing defining an interior space containing (a) laterally spaced-apart first and second permanent magnets, (b) first and second Hall Effect sensors, one Hall Effect sensor disposed proximate each of the first and second permanent magnets, and (c) a switch device being connected to said Hall Effect sensors and having a switching status varying in accordance with magnetic induction at said Hall Effect sensors; and a rocker-type switch button movably associated with the housing, the rocker-type switch button including laterally spaced-apart third and fourth permanent magnets associated therewith, and the rocker-type switch button having a neutral position and first and second applied positions. The first and third permanent magnets are spaced apart in opposition with one of the Hall Effect sensors disposed therebetween, and the second and fourth permanent magnets are spaced apart in opposition with the other of the Hall Effect sensors disposed therebetween. The first and third and second and fourth magnets, respectively, have poles of the same polarity facing one another. The first, second, third and fourth permanent magnets each generate a magnetic field, the opposing magnetic fields of, respectively, the first and third and second and fourth permanent magnets meeting at a boundary region in the space between said permanent magnets. In the neutral position of the rocker-type switch button, the boundary region of, respectively, the first and third and second and fourth permanent magnets is positioned above the Hall Effect sensor. In the first position of the rocker-type switch button, the boundary region of the first and third permanent magnets passes through and activates the Hall Effect sensor. In the second position of the rocker-type switch button, the boundary region of the second and fourth permanent magnets passes through and activates the Hall Effect sensor.

### BRIEF DESCRIPTION OF THE DRAWINGS

The foregoing and other features and advantages of the present invention may be better understood with reference to the specification and accompanying drawings, of which:

FIG. 1A is a perspective view of a magnetic field switch according to a first embodiment;

FIG. 1B is an exploded perspective view of a magnetic field switch according to the embodiment of FIG. 1, shown from a slightly above the switch;

FIG. 1C is an exploded perspective view of a magnetic field switch according to the embodiment of FIG. 1, shown from slightly below the switch;

FIG. 2 is a diagram depicting the orientation of the magnetic fields created by the opposing permanent magnets in the magnetic field switch according to the embodiment of FIGS. 1A through 1C;

FIG. 3A is a simplified cross-sectional view of the magnetic field switch according to the first embodiment, the switch being shown in a neutral position wherein the push button is in an un-depressed condition;

FIG. 3B is a simplified cross-sectional view of the magnetic field switch according to the first embodiment, the switch being shown in an applied position wherein the push button is in a depressed condition;

FIG. 4 is a cross-sectional view of an embodiment of the magnetic field switch wherein the permanent magnets are shaped to focus their respective magnetic fields in the area of the Hall Effect sensor;

FIG. 5 is a diagrammatic depiction of the magnetic field lines created by the permanent magnets shown in the embodiment of FIG. 4;

FIG. 6A is a cross-sectional view of a magnetic field switch according to a further embodiment of the present invention, wherein both permanent magnets are movable during operation of the switch, FIG. 6A showing the switch with the push-button in the neutral position thereof;

FIG. 6B is a cross-sectional view of a magnetic field switch of FIG. 6A, FIG. 6B showing the switch with the push-button in the applied position thereof;

FIGS. 7A and 7C through 7D are cross-sectional views of a further alternative embodiment of the present invention, according to which there is provided a switch with a rocker-type switch button;

FIG. 7B is an exploded cross-sectional view of the switch according to the embodiments of FIGS. 7A and 7C through 7D; and

FIG. 7E is a diagram depicting the orientation of the magnetic fields created by the opposing permanent magnets in the magnetic field switch according to the embodiment of FIGS. 7A through 7D.

### DETAILED DESCRIPTION

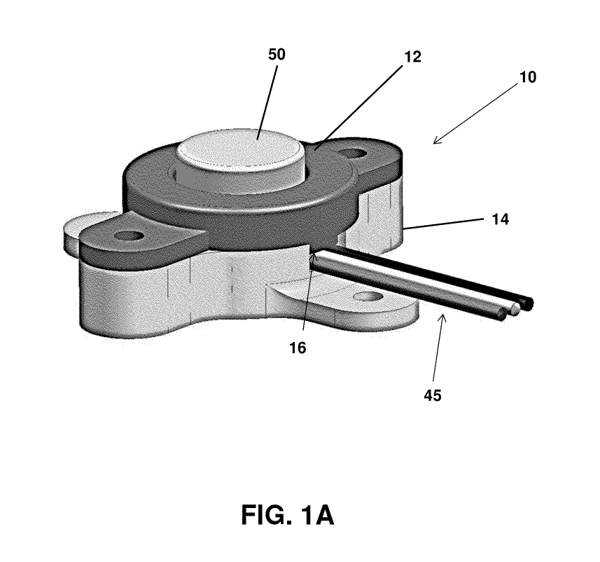

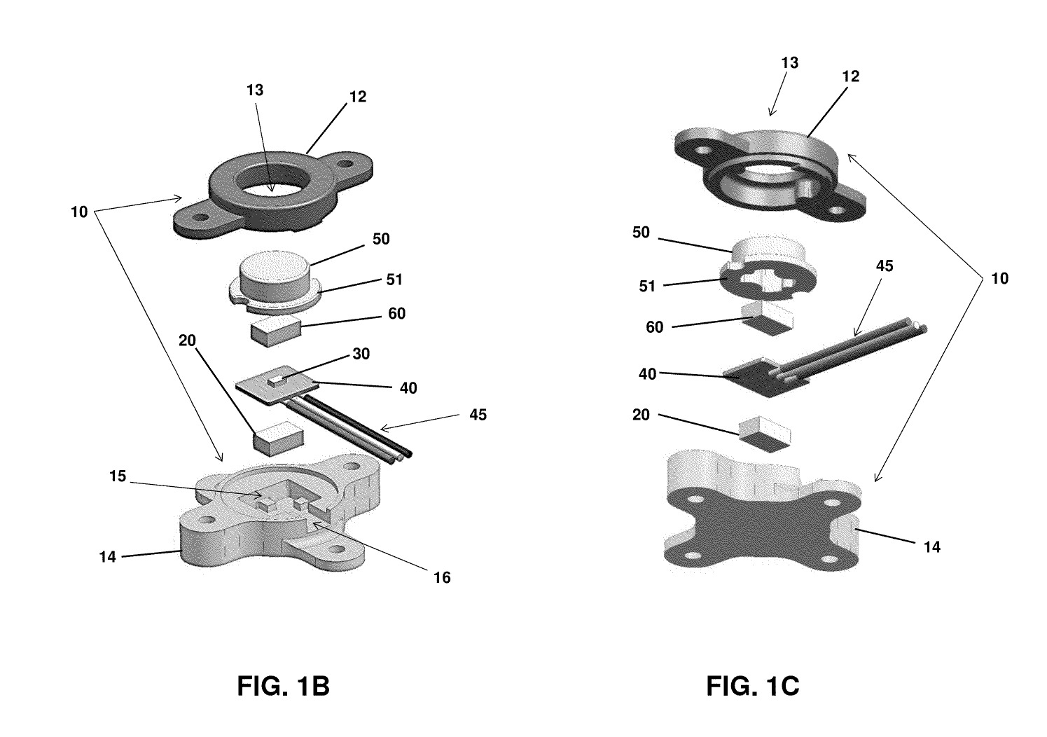

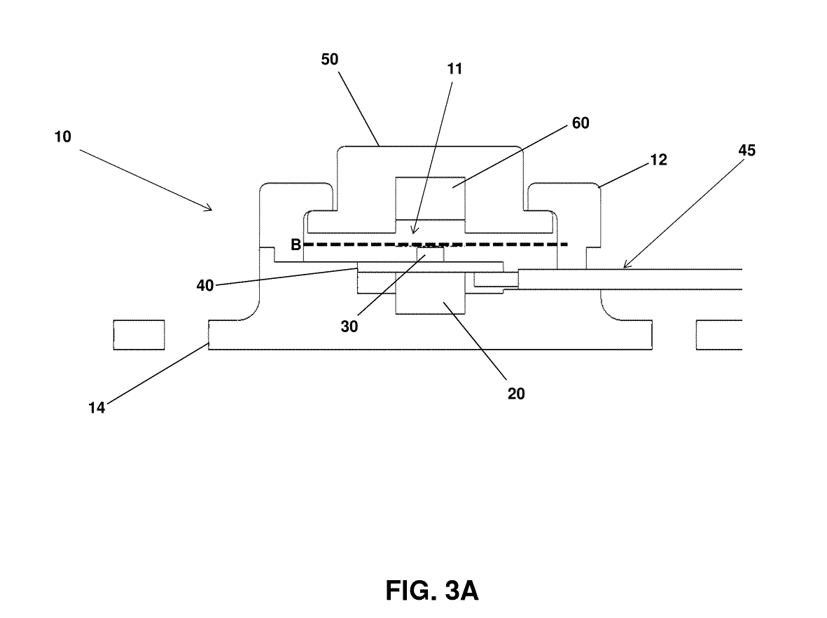

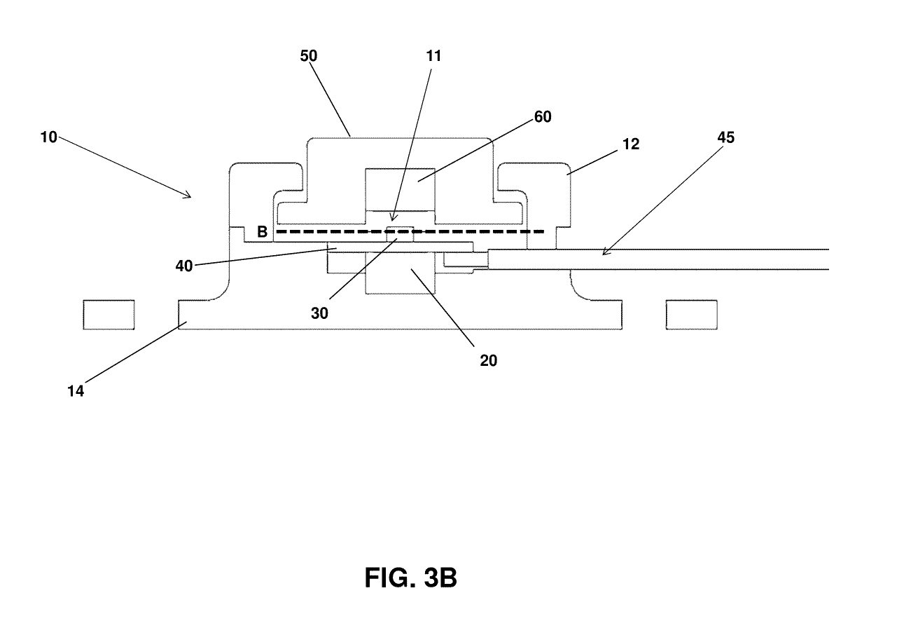

Referring now to the drawings, wherein like numerals indicate like or corresponding parts throughout the several views, there is disclosed in a first embodiment (FIGS. 1A through 3B) a magnetic field switch comprising: a housing 10 defining an interior space 11 containing a first permanent magnet 20, a Hall Effect sensor 30, and a switch device 40 connected to the Hall Effect sensor 30 and having a switching status varying in accordance with magnetic induction at the Hall Effect sensor 30; and a push-button 50 reciprocally movably associated with the housing 10, the push-button 50 including a second permanent magnet 60 associated therewith, and the push-button 50 having a neutral position (FIG. 3A) and an applied position (FIG. 3B).

The first 20 and second 60 permanent magnets are spaced apart with the Hall Effect sensor 30 and the switch device 40 disposed between them, as best shown in FIGS. 1, 3A and 3B.

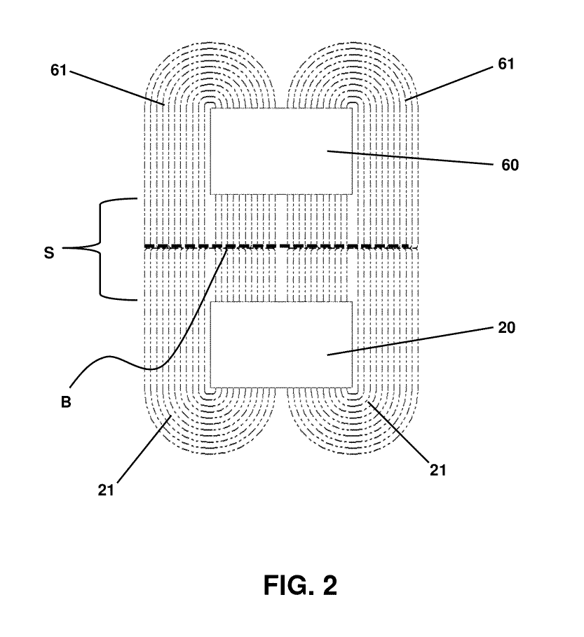

As best shown in FIG. 2, the first 20 and second 60 magnets have poles of the same polarity facing one another. The first 20 and second 60 permanent magnets each generate a magnetic field 21, 61, respectively, these opposing magnetic fields meeting at a boundary region (indicated by the dashed line B) in the space S between the first 20 and second 60 permanent magnets.

Housing 10, according to the illustrated embodiment, is shown to comprise mateable top 12 and base 14 portions. Top portion 12 includes an opening 13 therethrough dimensioned to receive and provide user access to the push-button 50. As shown, button 50 includes an annular flange 51 that is captured beneath the top portion 12 when the housing is in the assembled condition. Base portion 14 includes a cut-out 15 dimensioned to receive therein the first permanent magnet 20, Hall Effect sensor 30 and switch device 40. A channel 16 communicating with cut-out 15 receives three lead wires 45—namely a supply wire, a ground wire and a signal output wire—extending from switch device 40.

As required, housing 10 may be sealed so as to protect the internally disposed components from moisture, dirt, etc. Such sealing may be accomplished in any known fashion.

As will be appreciated from this disclosure, housing 10 and push-button switch 50 are preferably made of a non-ferromagnetic material, such as, for example, plastic and rubber, respectively.

Finally, it will be understood that the design of housing 10 as shown herein is exemplary only, and many variations thereof are possible, depending on the particular application of the magnetic field switch. Accordingly, the exemplified design of housing 10 is not to be construed as limiting of the invention, which may be adapted to numerous alternative designs of the housing 10.

In the design of the illustrated embodiment, switch device 40 and Hall Effect sensor 30 are part of an integrated circuit, such as in the form of a printed circuit board (“PCB”). Other known components may be included as part of the integrated circuit, such as a resistor and/or a capacitor to protect the Hall Effect sensor from interference. The PCB may be sealed so as to prevent the intrusion of debris and moisture, being encased, for instance, in a sealant, potting, casing, etc. as may be appropriate to the particular application of the switch.

According to the illustrated embodiment, first permanent magnet 20 is fixed underneath the PCB, while the second permanent magnet 60 is associated with the push-button 50 so as to be suspended above the Hall effect sensor 30. As will be understood by those skilled in the art, this arrangement causes the magnets 20, 60 to repel each other, thereby negating the need for any kind of mechanical spring or other mean to bias push-button 50 to the neutral position (FIG. 3A).

As shown in FIG. 3A, the boundary region B is positioned immediately above the Hall Effect sensor 30; while, in the applied position (FIG. 3B) of the push-button 50, the boundary region B passes through and activates the Hall Effect sensor 30. More particularly, the boundary region B created by the opposing magnetic fields resides approximately 0.1 mm above the Hall Effect sensor 30 in the illustrated embodiment. By so positioning the boundary region B, the magnetic field switch advantageously has a short yet clearly defined activation stroke. Furthermore, it will be appreciated with the benefit of this disclosure that this activation stroke can be tuned by adjusting the thickness of the PCB, offsetting the relative strengths of the permanent magnets 20, 60 from one another, etc.

Per convention, operation of the switch is effected by user actuation of the push-button 50, which causes the second permanent magnet 60 to be moved toward the first permanent magnet 20 positioned below the Hall Effect sensor. This movement changes the position of the magnetic field boundary region B. More particularly, the boundary region B is moved from a position immediately above the Hall Effect sensor 30 (FIG. 3A) through the Hall Effect sensor (FIG. 3B). This change in induction is detected by the Hall Effect sensor 30 and translated into a signal by the switch device 40 into a switching status to effect operation of some downstream component (such as a light, window, power latch, etc.). Conversely, the change in induction detected by the Hall Sensor when the push-button 50 is returned to the neutral position is translated in a signal by the switch device 40 into a different (e.g., opposite) switching status.

In the illustrated embodiment, the switching threshold of the Hall Effect sensor 30 corresponds to less than a millimeter of travel of the boundary region B from its location in the neutral position. As those skilled in the art will appreciate, however, the foregoing value is exemplary only of the specific embodiments. Depending on the characteristic values of the Hall Effect sensor being used and on the other components, the threshold values may vary.

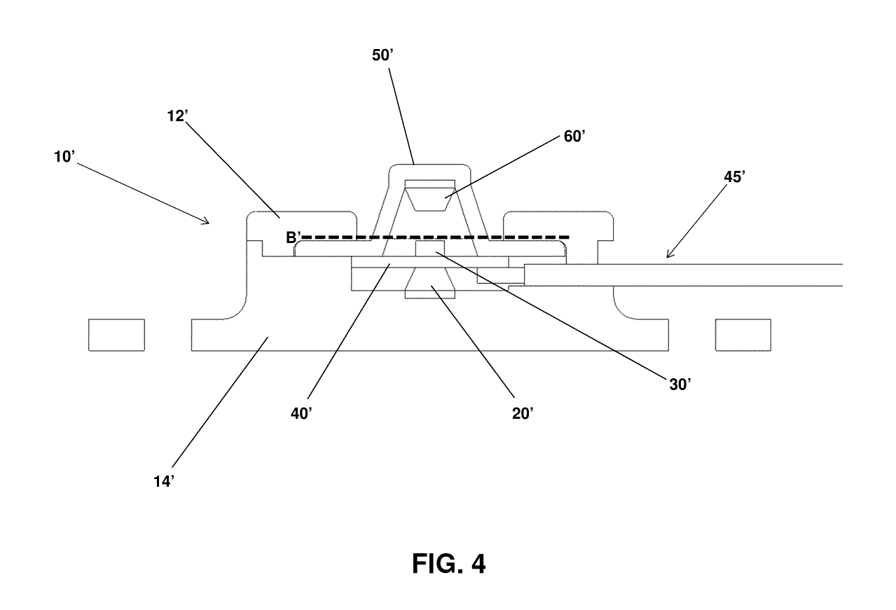

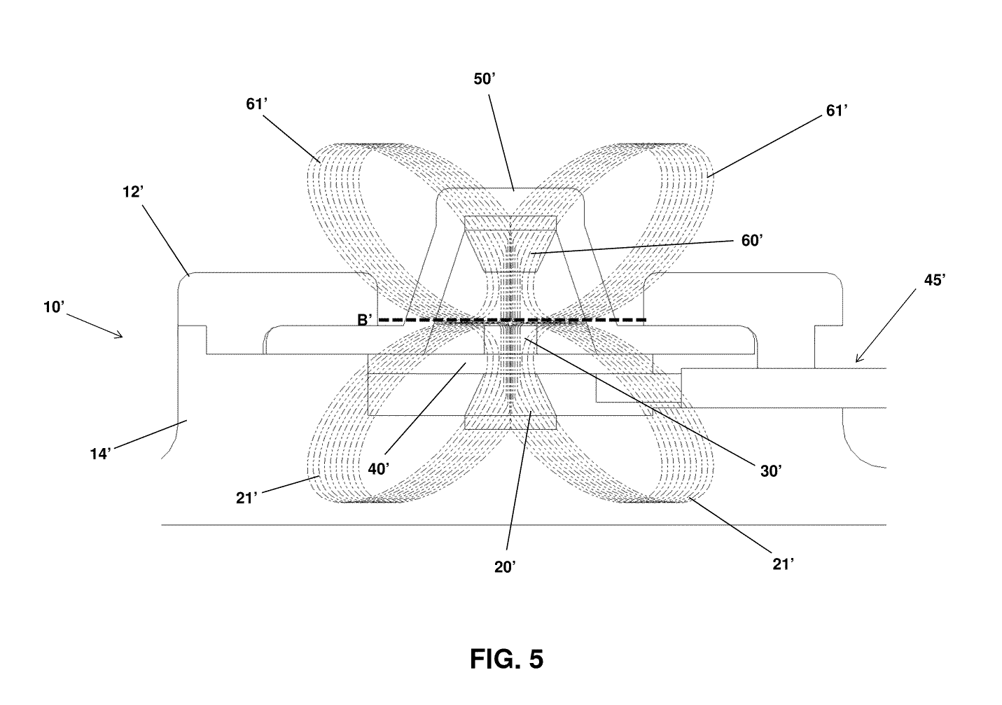

Referring next to FIGS. 4 and 5, the first 20′ and second 60′ permanent magnets may, in one form of the invention, be shaped so as to concentrate the density of the magnetic field 21′, 61′, respectively, of each magnet 20′, 60′ proximate the space between the first and second magnets. In the illustrated embodiment, the first 20′ and second 60′ permanent magnets are, more particularly, each frusto-conically shaped. Moreover, and as shown in FIG. 5, each of the first 20′ and second 60′ magnets is arranged so that they taper towards each other in the magnetic switch.

According to the embodiments of FIGS. 1A through 5, the first permanent magnet 20, 20′ is fixed in position within the housing 10, 10′.

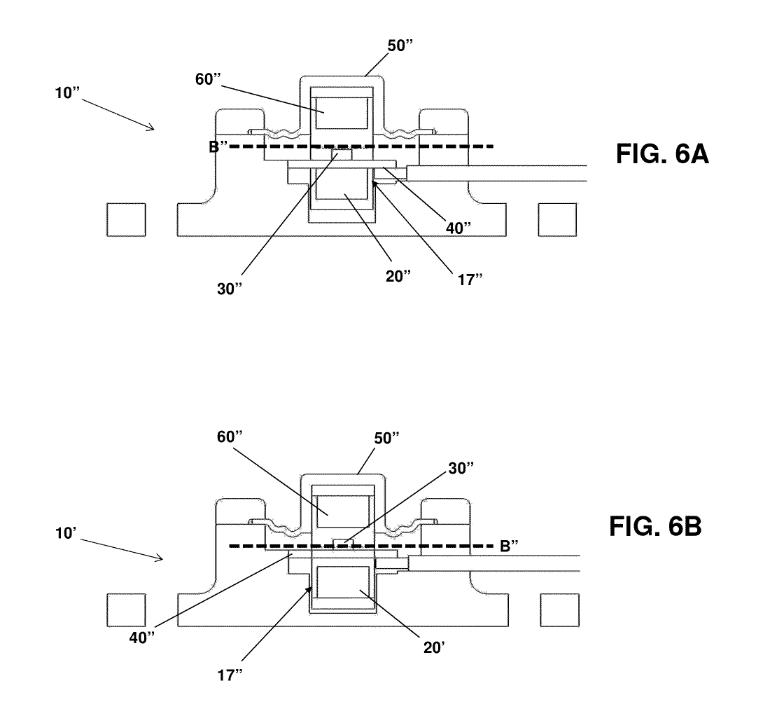

Referring now to FIGS. 6A and 6B, there is shown an alternative embodiment of the invention wherein the first permanent magnet 20″ is moveably disposed within the housing 10″.

Except as specified below, the embodiment of FIGS. 6A and 6B is immaterially different from the embodiments of FIGS. 1 through 5.

More particularly, the embodiment of FIGS. 6A and 6B is characterized in that the housing 10″ is modified to include a guide slot or track 17″ of sufficient vertical dimensions to permit floating movement of the first permanent magnet 20″ corresponding to movement of the second permanent magnet 60″ in response to actuation of the push-button switch 50″. According to this embodiment, depressing the push-button switch 51′ simply moves the boundary region B″ between the opposing magnetic fields through the Hall Effect sensor 30″.

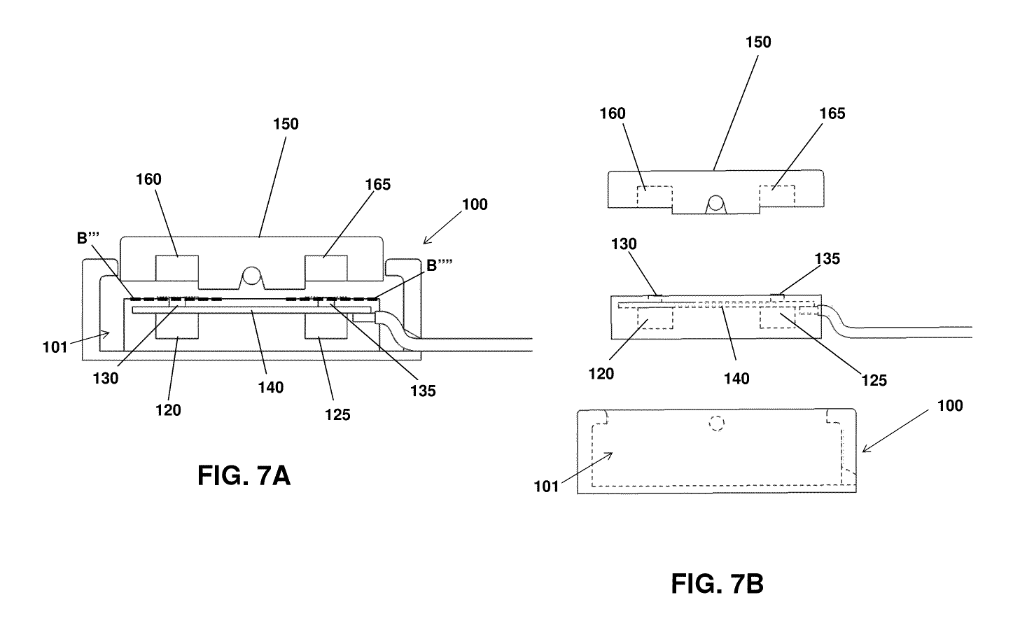

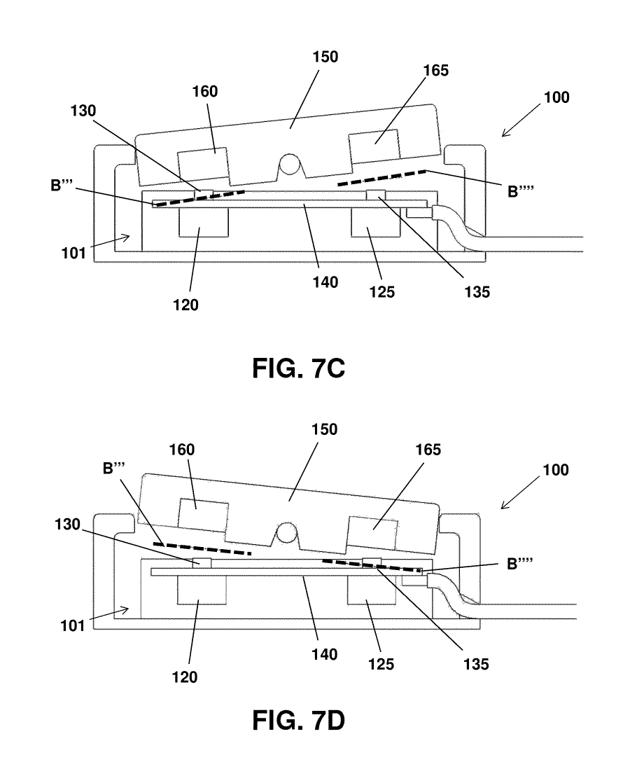

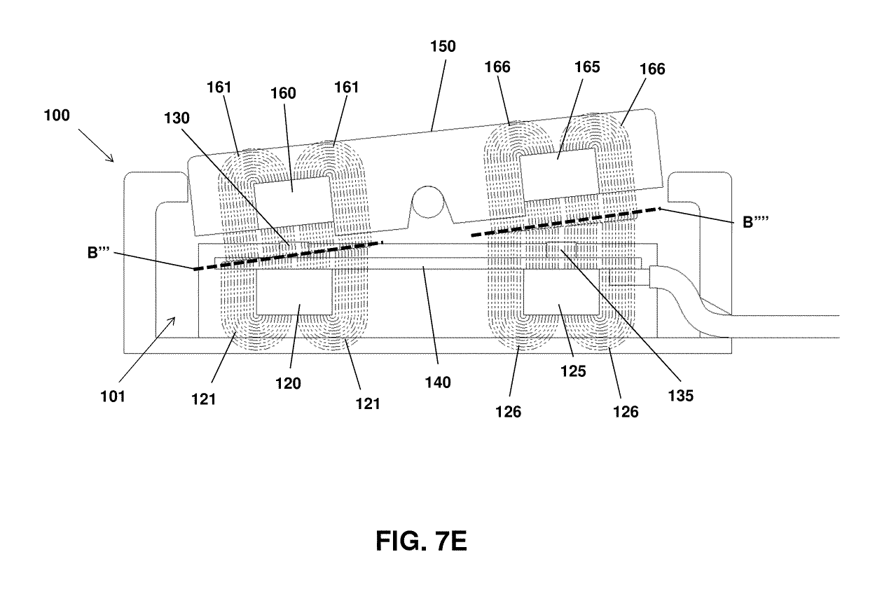

Turning next to FIGS. 7A through 7E, there is shown a further embodiment of a magnetic field switch comprising: a housing 100 defining an interior space 101 containing laterally spaced-apart first 120 and second 125 permanent magnets; first and second Hall Effect sensors 130, 135, one Hall Effect sensor 130, 135 disposed proximate each of the first 120 and second 125 permanent magnets; and a switch device 140 being connected to the Hall Effect sensors 130, 135 and having a switching status varying in accordance with magnetic induction at the Hall Effect sensors 130, 135; and a rocker-type switch button 150 pivotally associated with the housing, the rocker-type switch button including laterally spaced-apart third 160 and fourth 165 permanent magnets associated therewith, and the rocker-type switch button 150 having a neutral position (FIG. 7A) and first (FIG. 7B) and second (FIG. 7C) applied positions.

Except as specified below, the embodiment of FIGS. 7A and 7E is immaterially different from the embodiment of FIGS. 1 through 5.

The first 120 and third 160 permanent magnets are spaced apart in opposition with one of the Hall Effect sensors 130 disposed therebetween, and the second 125 and fourth 165 permanent magnets are spaced apart in opposition with the other of the Hall Effect sensors 135 disposed therebetween. As shown, the first 120 and third 160 and second 125 and fourth 165 magnets, respectively, have poles of the same polarity facing one another. The first 120, second 125, third 160 and fourth 165 permanent magnets each generate a magnetic field. The opposing magnetic fields 121, 161 and 126, 166 of, respectively, the first 120 and third 160 and second 125 and fourth 165 permanent magnets meet at a boundary region B″′, B″″ in the space between the permanent magnets (see FIG. 7E). In the neutral position (FIG. 7A) of the rocker-type switch button 150, the boundary region B″′, B″″ of, respectively, the first 120 and third 160 and second 125 and fourth 165 permanent magnets is positioned above each Hall Effect sensor 130, 135. In the first position (FIG. 7C) of the rocker-type switch button 150, the boundary region B″ of the first 120 and third 160 permanent magnets passes through and activates the Hall Effect sensor 130. And, in the second position (FIG. 7D) of the rocker-type switch button 150, the boundary region B″″ of the second 125 and fourth 165 permanent magnets passes through and activates the Hall Effect sensor 135.

As will be understood by those skilled in the art, this arrangement of the magnets 120, 160 and 125, 165, respectively, in opposition causes them to repulse away from one another, thereby automatically tending to center the rocker-type switch button 150 in the neutral position. Accordingly, the need for any kind of mechanical spring or other mean to bias rocker-type switch button 150 to the neutral position is negated.

As with the embodiment of FIGS. 1 through 5, the housing 100 may be sealed so as to prevent the intrusion of debris and moisture into the housing, thereby increasing the operational lifetime of the switch. Also as with the embodiment of FIGS. 4 and 5, the permanent magnets 120, 125, 160, 165 may, optionally, be shaped so as to concentrate the density of the magnetic fields of each magnet 120, 125, 160, 165 proximate the space between opposed pairs of these magnets. For instance, each permanent magnet 120, 125, 160, 165 may be frusto-conically shaped and, moreover, arranged so that they taper towards each other in the magnetic switch.

It will be appreciated from the foregoing disclosure that the magnetic field switch of the present invention may be utilized in a wide variety of applications, and especially applications where switches are subjected to high cycle rates. Without limitations, exemplary switches include switches for vehicle applications, such as door handle switches, lift-gate switches, interior light switches, window up/down switches, etc.

By its design and construction, the present invention in its various embodiments addresses drawbacks associated with prior art switches, as follows: First, the elimination of numerous moving parts. Due to the lack of a spring or moving seal, the floating button and one or more magnets are the only moving parts in the device. Moreover, this floating action of the button allows for loose tolerances as well as minimal, if any, wear on the button. Second, the invention provides a nearly unlimited cycle life. With no contacts, springs, seals, etc., the switch of the present invention has no perceptible limitations to the number of cycles it can endure under normal operation. Third, the present invention provides electronic versatility. While the basic switch circuitry is simple, it can be expanded with peripheral components in order to take into account EMC considerations, voltage regulation, light emission, or other ancillary functions. Fourth, the present invention may be embodied in a relatively small sized unit. The relatively small size of switch that can be made according to the present invention is advantageous versus conventional long-life switches, which generally include large seals and casings. This allows the switch to be put into slimmer profiles designs while simultaneously increasing durability and robustness.

Many modifications and variations of the present disclosure, all of which will be apparent to those skilled in the art having the benefit of this disclosure, are possible in light of the above teachings. Therefore, within the scope of the appended claims, the present disclosure may be practiced other than as specifically described.

The invention in which an exclusive property or privilege is claimed is defined as follows:

1. A magnetic field switch, comprising:
a housing defining an interior space containing
(a) a first permanent magnet;
(b) a Hall Effect sensor; and
(c) a switch device being connected to said Hall Effect sensor and having a switching status varying in accordance with magnetic induction at said Hall Effect sensor; and
a push-button reciprocally movably associated with the housing, the push-button including a second permanent magnet associated therewith, and the push-button having a neutral position and an applied position;
wherein the first and second permanent magnets are spaced apart with the Hall Effect sensor and the switch device disposed therebetween;
wherein the first and second magnets have poles of the same polarity facing one another;
wherein the first and second permanent magnets each generate a magnetic field, the opposing magnetic fields meeting at a boundary region in the space between the first and second permanent magnets;
wherein, in the neutral position of the push-button, the boundary region is positioned immediately above the Hall Effect sensor; and
wherein, in the applied position of the push-button, the boundary region passes through and activates the Hall Effect sensor.

2. The magnetic field switch of claim 1, wherein the housing is a sealed housing.

3. The magnetic field switch of claim 1, wherein the first and second permanent magnets are shaped so as to concentrate the density of the magnetic field of each magnet proximate the space between the first and second magnets.

4. The magnetic field switch of claim 3, wherein the first and second permanent magnets are each frusto-conically shaped, with each of the first and second magnets arranged so that they taper towards each other.

5. The magnetic field switch of claim 1, wherein, in the neutral position of the push-button, the boundary region is positioned approximately 0.1 mm above the Hall Effect sensor.

6. The magnetic field switch of claim 1, wherein the first permanent magnet is fixed in position within the housing.

7. The magnetic field switch of claim 1, wherein the first permanent magnet is movably disposed within the housing.

8. A magnetic field switch, comprising:
a housing defining an interior space containing
(a) laterally spaced-apart first and second permanent magnets;
(b) first and second Hall Effect sensors, one Hall Effect sensor disposed proximate each of the first and second permanent magnets; and
(c) a switch device being connected to said Hall Effect sensors and having a switching status varying in accordance with magnetic induction at said Hall Effect sensors; and
a rocker-type switch button movably associated with the housing, the rocker-type switch button including laterally spaced-apart third and fourth permanent magnets associated therewith, and the rocker-type switch button having a neutral position and first and second applied positions;
wherein the first and third permanent magnets are spaced apart in opposition with one of the Hall Effect sensors disposed therebetween, and the second and fourth permanent magnets are spaced apart in opposition with the other of the Hall Effect sensors disposed therebetween;
wherein the first and third and second and fourth magnets, respectively, have poles of the same polarity facing one another;
wherein the first, second, third and fourth permanent magnets each generate a magnetic field, the opposing magnetic fields of, respectively, the first and third and second and fourth permanent magnets meeting at a boundary region in the space between said permanent magnets;
wherein, in the neutral position of the rocker-type switch button, the boundary region of, respectively, the first and third and second and fourth permanent magnets is positioned above the Hall Effect sensor;
wherein, in the first position of the rocker-type switch button, the boundary region of the first and third permanent magnets passes through and activates the Hall Effect sensor; and
wherein, in the second position of the rocker-type switch button, the boundary region of the second and fourth permanent magnets passes through and activates the Hall Effect sensor;

9. The magnetic field switch of claim 8, wherein the housing is a sealed housing.

10. The magnetic field switch of claim 8, wherein the first, second, third and fourth magnets permanent magnets are shaped so as to concentrate the density of the magnetic field of each magnet proximate the space between the first and third and second and fourth magnets, respectively.

11. The magnetic field switch of claim 10, wherein the first, second, third and fourth permanent magnets are each frusto-conically shaped, with each of the first and third and second and fourth magnets arranged so that they taper towards each other.
